(19) United States
(12) Patent Application Publication
(10) Pub. No.: US 2025/0143194 A1
(43) Pub. Date: May 1, 2025

(54) RESISTIVE RANDOM-ACCESS MEMORY (RRAM) DEVICES WITH DOPED SWITCHING OXIDES

(71) Applicant: TetraMem Inc., Fremont, CA (US)

(72) Inventors: Minxian Zhang, Amherst, MA (US); Mingche Wu, San Jose, CA (US); Ning Ge, Danville, CA (US)

(73) Assignee: TetraMem Inc., Fremont, CA (US)

(21) Appl. No.: 18/499,596

(22) Filed: Nov. 1, 2023

(51) Int. Cl. H10N 70/00; H10B 63/00; H10N 70/20

(52) U.S. Cl. CPC H10N 70/8833; H10B 63/00; H10N 70/023; H10N 70/026; H10N 70/24; H10N 70/841

(57) ABSTRACT

The present disclosure provides resistive random-access memory (RRAM) devices and methods for making the same. An RRAM device may include a first electrode, a second electrode including a conductive material, and a switching oxide layer fabricated between the first electrode and the second electrode. The switching oxide layer includes a base oxide and a dopant oxide that is more chemically stable than the base oxide. The first electrode includes a non-reactive material that is not reactive to the base oxide or the dopant oxide. In some embodiments, the base oxide is Ta₂O₅, and the dopant oxide is Al₂O₃, SiO₂, ZrO₂, Sc₂O₃, or Y₂O₃.

### TECHNICAL FIELD

The implementations of the disclosure generally relate to resistive random-access memory (RRAM) devices and, more specifically, to RRAM devices with doped switching oxides and methods for fabricating the same.

### BACKGROUND

A resistive random-access memory (RRAM) device is a two-terminal passive device with tunable and non-volatile resistance. The resistance of the RRAM device may be electrically switched between a high-resistance state (HRS) and a low-resistance state (LRS) by applying suitable programming signals to the RRAM device. RRAM devices may be used to form crossbar arrays that may be used to implement in-memory computing applications, non-volatile solid-state memory, image processing applications, neural networks, etc.

### SUMMARY

The following is a simplified summary of the disclosure to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

According to one or more aspects of the present disclosure, a resistive random-access memory (RRAM) device is provided. The RRAM device includes a first electrode; a second electrode including a conductive material; and a switching oxide layer fabricated between the first electrode and the second electrode. The switching oxide layer includes a base oxide and a dopant oxide that is more chemically stable than the base oxide. The first electrode includes a non-reactive material that is not reactive to the base oxide or the dopant oxide.

In some embodiments, the base oxide includes at least one of HfOₓ or TaO_{y}, wherein x≤2.0, and wherein y≤2.5.

In some embodiments, the base oxide includes Ta₂O₅, and the dopant oxide includes at least one of Al₂O₃, SiO₂, ZrO₂, Sc₂O₃, or Y₂O₃.

In some embodiments, the non-reactive material in the first electrode includes at least one of titanium nitride, tantalum nitride, platinum, palladium, iridium, or ruthenium.

In some embodiments, the second electrode further includes a layer of titanium and a layer of tantalum.

In some embodiments, the RRAM device further includes an interface layer positioned between the switching oxide layer and the second electrode.

In some embodiments, the interface layer positioned between the switching oxide layer and the second electrode includes a discontinuous film of a dielectric material, wherein at least a portion of the second electrode is deposited on the switching oxide layer.

In some embodiments, the RRAM device further includes a first interface layer positioned between the first electrode and the switching oxide layer.

In some embodiments, the RRAM device further includes a second interface layer positioned between the second electrode and the switching oxide layer.

According to one or more aspects of the present disclosure, methods for fabricating an RRAM device are provided. The methods include: fabricating, on a first electrode, a switching oxide layer on the first electrode including a base oxide and a dopant oxide, wherein the dopant oxide is more chemically stable than the base oxide; and fabricating a second electrode on the switching oxide layer.

In some embodiments, fabricating the switching oxide layer includes performing physical vapor deposition (PVD) using a single target and a single power source. The single target includes the base oxide and the dopant oxide.

In some embodiments, the first electrode, the switching oxide layer, and the second electrode are fabricated in the same physical vapor deposition (PVD) processing chamber.

In some embodiments, fabricating the switching oxide layer includes performing a physical vapor deposition (PVD) co-sputtering process.

In some embodiments, fabricating the switching oxide layer includes depositing the base oxide and the dopant oxide using an atomic layer deposition (ALD) process.

In some embodiments, the techniques described herein relate to a method, further including fabricating an interface layer on the switching oxide layer.

In some embodiments, the interface layer includes a discontinuous film of a dielectric material, wherein at least a portion of the second electrode is deposited on the switching oxide layer including the base oxide and the dopant oxide.

In some embodiments, the dielectric material includes at least one of Al₂O₃, SiO₂, ZrO₂, Sc₂O₃, or Y₂O₃.

In some embodiments, the methods further include fabricating a first interface layer including a first dielectric material on the first electrode, wherein the switching oxide layer is fabricated on the first interface layer; and fabricating a second interface layer including a second dielectric material on the switching oxide layer, wherein the second electrode is fabricated on the second interface layer.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding.

FIG. 1 is a schematic diagram illustrating an example of a crossbar circuit in accordance with some embodiments of the present disclosure.

FIG. 2 is a schematic diagram illustrating an example of a cross-point device in accordance with some embodiments of the present disclosure.

FIGS. 3A, 3B, 3C, and 3D illustrate cross-sectional views of structures for fabricating an RRAM device in accordance with some embodiments of the present disclosure.

FIGS. 3E and 3F illustrate RRAM devices of FIG. 3C and/or FIG. 3D at a low resistance state (LRS) and a high resistance state (HRS), respectively.

FIGS. 4A-4F are schematic diagrams illustrating cross-sectional views of example structures of RRAM devices in accordance with one implementation of the present disclosure.

FIGS. 5A-5D are schematic diagrams illustrating cross-sectional views of example structures of RRAM devices in accordance with another implementation of the present disclosure.

FIGS. 6A-6D are schematic diagrams illustrating cross-sectional views of example structures of RRAM devices in accordance with another implementation of the present disclosure.

FIGS. 7-10 are flow diagrams illustrating example processes for fabricating an RRAM device according to some embodiments of the present disclosure.

FIG. 11A is an example Ta—Al—O ternary phase diagram.

FIG. 11B is an example Ta—Zr—O ternary phase diagram.

FIG. 11C is an example Ta—Hf—O ternary phase diagram.

FIG. 11D is an example Ta—Sc—O ternary phase diagram.

FIG. 11E is an example Ta—Y—O ternary phase diagram.

FIGS. 12A and 12B are diagrams plotting the resistance of example RRAM devices according to the present disclosure over a number of operation cycles.

FIGS. 13A and 13B are diagrams plotting the conductance of an example RRAM device according to the present disclosure over time at room temperature and 125° C., respectively.

### DETAILED DESCRIPTION

Aspects of the disclosure provide resistive random-access memory (RRAM) devices and methods for fabricating the RRAM devices. RRAM devices (also referred to as memristors) are a type of two-terminal electronic device exhibiting both memory and non-volatile resistance.

In accordance with some embodiments of the present disclosure, an RRAM device may include a first electrode, a second electrode, and a switching oxide layer positioned between the first electrode and the second electrode. The first electrode may include a non-reactive metal, such as platinum (Pt), palladium (Pd), ruthenium (Ru), etc. The second electrode may include a reactive metal, such as tantalum (Ta). The first electrode is also referred to as the “non-reactive electrode.” The second electrode may be referred to as the “reactive electrode.” The switching oxide layer may include a base oxide and one or more dopant oxides that are more chemically stable than the base oxide. The base oxide may be, for example, tantalum oxide (TaO_{y}). The dopant oxides may include, for example, Al₂O₃, SiO₂, ZrO₂, Sc₂O₃, or Y₂O₃. In some embodiments, the RRAM device may further include an interface layer positioned between the first electrode and the switching oxide layer. Each of the interface layers may include a discontinuous film of a dielectric material. The RRAM devices described herein present advanced multilevel resistance, linearity, and read stability.

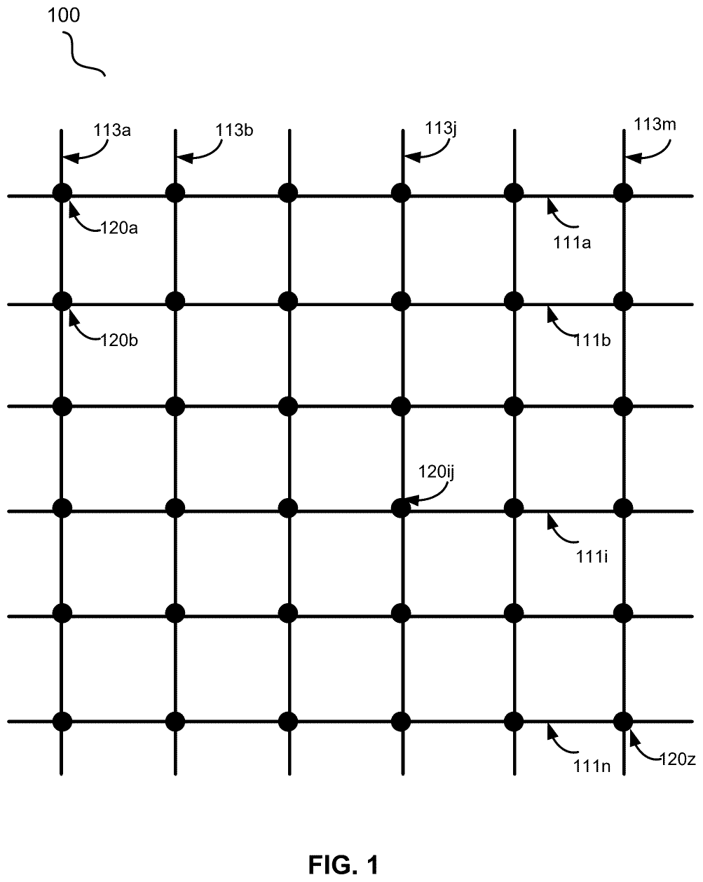

FIG. 1 is a schematic diagram illustrating an example 100 of a crossbar circuit in accordance with some embodiments of the present disclosure. As shown, crossbar circuit 100 may include a plurality of interconnecting electrically conductive wires, such as one or more row wires 111a, 111b, . . . , 111i, . . . , 111n, and column wires 113a, 113b, . . . , 113j, . . . , 113m for an n-row by m-column crossbar array. The crossbar circuit 100 may further include cross-point devices 120a, 120b, . . . , 120z, etc. Each of the cross-point devices may connect a row wire and a column wire. For example, the cross-point device 120ij may connect the row wire 111i and the column wire 113j. In some embodiments, crossbar circuit 100 may further include digital to analog converters (DAC, not shown), analog to digital converters (ADC, not shown), switches (not shown), and/or any other suitable circuit components for implementing a crossbar-based apparatus. The number of the column wires 113a-m and the number of the row wires 111a-n may or may not be the same.

Row wires 111a-n may include a first row wire 111a, a second row wire 111b, . . . , 111i, . . . , and an n-th row wire 111n. Each of row wires 111a, . . . , 111n may be and/or include any suitable electrically conductive material. In some embodiments, each row wire 111a-n may be a metal wire.

Column wires 113a-m may include a first column wire 113a, a second column wire 113b, . . . , and an m-th column wire 113m. Each of column wires 113a-m may be and/or include any suitable electrically conductive material. In some embodiments, each column wire 113a-m may be a metal wire.

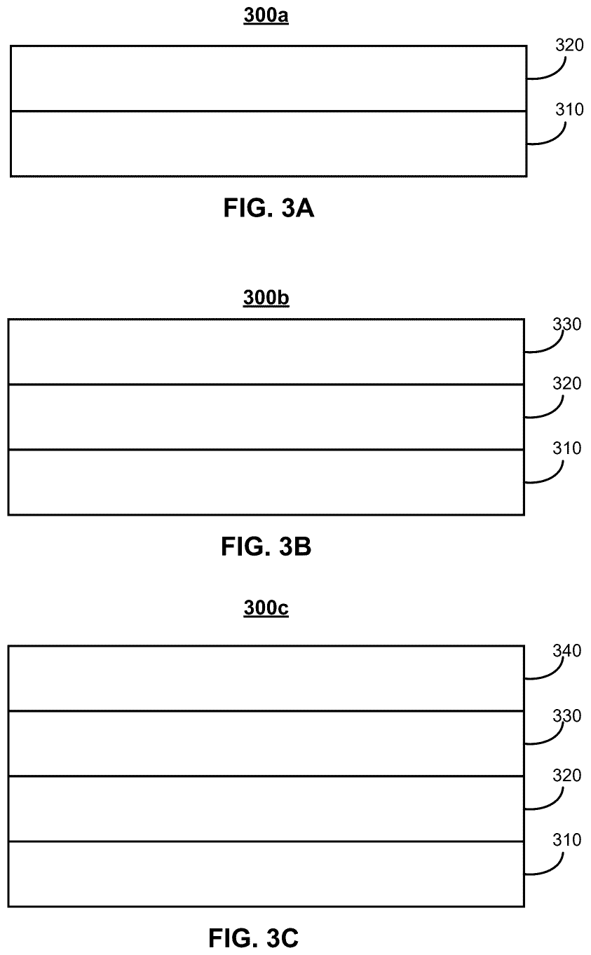

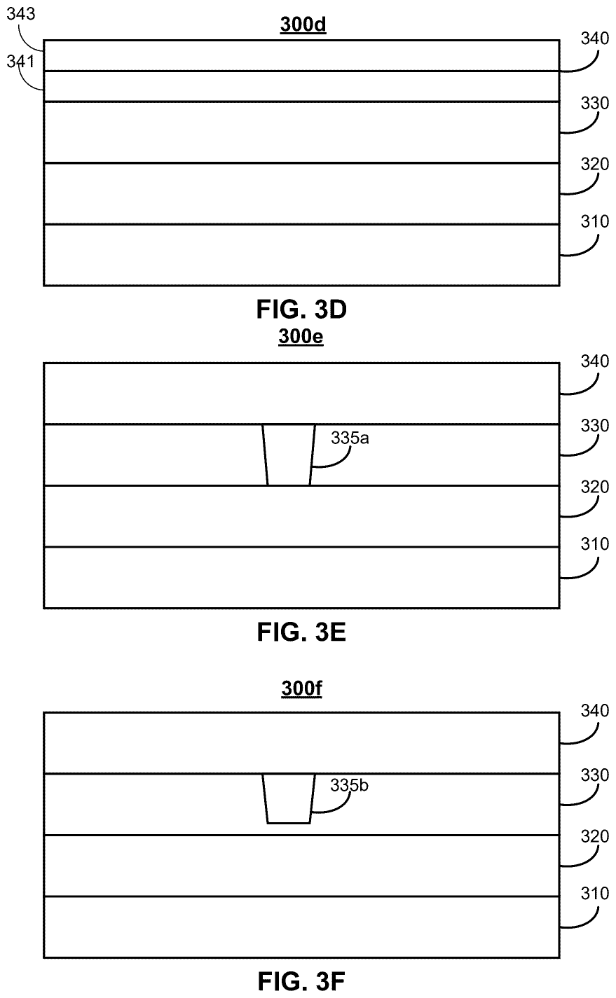

Each cross-point device 120a-z may be and/or include any suitable device with tunable resistance, such as a memristor, PCM (phase change memory) devices, floating gates, spintronic devices, resistive random-access memory (RRAM), static random-access memory (SRAM), etc. In some embodiments, one or more cross-point devices 120a-z may include an RRAM device as described in connection with FIGS. 3A-6D.

Crossbar circuit 100 may perform parallel weighted voltage multiplication and current summation. For example, an input voltage signal may be applied to one or more rows of crossbar circuit 100 (e.g., one or more selected rows). The input signal may flow through the cross-point devices of the rows of the crossbar circuit 100. The conductance of the cross-point device may be tuned to a specific value (also referred to as a “weight”). By Ohm's law, the input voltage multiplies the cross-point conductance and generates a current from the cross-point device. By Kirchhoff's law, the summation of the current passing the devices on each column generates the current as the output signal, which may be read from the columns (e.g., outputs of the ADCs). According to Ohm's law and Kirchhoff's current law, the input-output relationship of the crossbar array can be represented as I=VG, wherein I represents the output signal matrix as current; V represents the input signal matrix as voltage; and G represents the conductance matrix of the cross-point devices. As such, the input signal is weighted at each of the cross-point devices by its conductance according to Ohm's law. The weighted current is output via each column wire and may be accumulated according to Kirchhoff's current law. This may enable in-memory computing (IMC) via parallel multiplications and summations performed in the crossbar arrays.

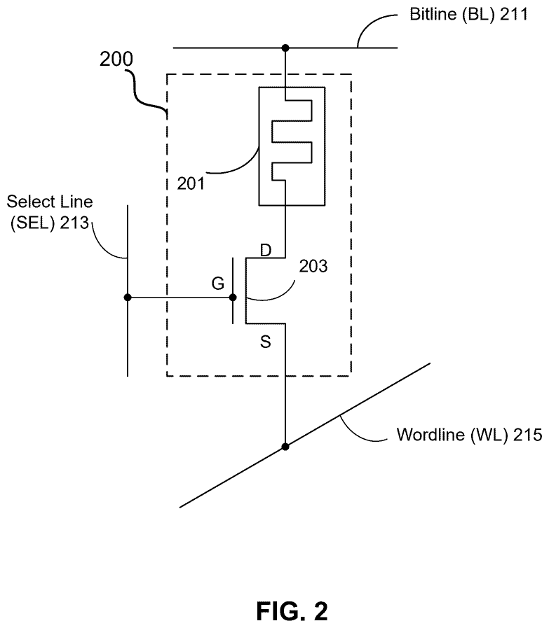

FIG. 2 is a schematic diagram illustrating an example 200 of a cross-point device in accordance with some embodiments of the present disclosure. As shown, cross-point device 200 may connect a bitline (BL) 211, a select line (SEL) 213, and a wordline (WL) 215. The bitline 211 and the wordline 215 may be a column wire and a row wire as described in connection with FIG. 1, respectively.

Cross-point device 200 may include an RRAM device 201 and a transistor 203. A transistor may include three terminals, which may be marked as gate (G), source(S), and drain (D), respectively. The transistor 203 may be serially connected to RRAM device 201. As shown in FIG. 2, the first electrode of the RRAM device 201 may be connected to the drain of transistor 203. The second electrode of the RRAM device 201 may be connected to the bitline 211. The source of the transistor 203 may be connected to the wordline 215. The gate of the transistor 203 may be connected to the select line 213. RRAM device 201 may include one or more RRAM devices as described in connection with FIGS. 3A-6D below. Cross-point device 200 may also be referred to as a one-transistor-one-resistor (1T1R) configuration. The transistor 203 may perform as a selector as well as a current controller, which may set the current compliance to the RRAM device 201 during programming. The gate voltage on transistor 203 can set current compliances to cross-point device 200 during programming and can thus control the conductance and analog behavior of cross-point device 200. For example, when cross-point device 200 is set from a high-resistance state to a low-resistance state, a set signal (e.g., a voltage signal, a current signal) may be provided via the bitline (BL) 211. Another voltage, also referred to as a select voltage or gate voltage, may be applied via the select line (SEL) 213 to the transistor gate to open the gate and set the current compliance, while the wordline (WL) 215 may be set to ground. When cross-point device 200 is reset from the low-resistance state to the high-resistance state, a gate voltage may be applied to the gate of the transistor 203 via the select line 213 to open the transistor gate. Meanwhile, a reset signal may be sent to the RRAM device 201 via the wordline 215, while the bitline 211 may be set to ground.

FIGS. 3A, 3B, 3C, and 3D illustrate cross-sectional views of structures 300a, 300b, 300c, and 300d for fabricating an RRAM device in accordance with some embodiments of the present disclosure. FIGS. 3E and 3F illustrate RRAM devices 300e and 300f corresponding to RRAM devices 300c and/or 300d at a low resistance state (LRS) and a high resistance state (HRS), respectively.

As shown in FIG. 3A, a substrate 310 may be provided. A first electrode 320 may be fabricated on the substrate 310. The substrate 310 may include one or more layers of any suitable material that may serve as a substrate for an RRAM device, such as silicon (Si), silicon dioxide (SiO₂), silicon nitride (Si₃N₄), aluminum oxide (Al₂O₃), aluminum nitride (AlN), etc. In some embodiments, the substrate 310 may include diodes, transistors, interconnects, integrated circuits, one or more other RRAM devices, etc. In some embodiments, the substrate 310 may include a driving circuit including one or more electrical circuits (e.g., an array of electrical circuits) that may be individually controllable. In some embodiments, the driving circuit may include one or more complementary metal-oxide-semiconductor (CMOS) drivers.

The first electrode 320 may include any suitable material that is electronically conductive and non-reactive to the switching oxide layer to be fabricated on the first electrode 320 during RRAM operations (also referred to as the “non-reactive” material). As an example, the first electrode 320 may include a non-reactive metal, such as platinum (Pt), palladium (Pd), iridium (Ir), ruthenium (Ru), etc. As another example, the first electrode 320 may include a metal nitride having suitable chemical stability so that it will not react with oxygen during RRAM switching, such as titanium nitride (TiN), tantalum nitride (TaN), etc. The first electrode 320 may also be referred to as the “non-reactive electrode.”

Referring to FIG. 3B, a switching oxide layer 330 may be fabricated on the first electrode 320. The switching oxide layer 330 may include one or more transition metal oxides, such as TaO_{y}, HfOₓ, TiOₓ, NbOₓ, ZrOₓ, etc., in binary oxides, ternary oxides, and high-order oxides. In some embodiments, the chemical stability of the non-reactive material in the first electrode 320 may be higher than that of metal in the transition metal oxide(s) in switching oxide layer 330. In some embodiments, the transition metal oxide(s) include at least one of HfOₓ or TaO_{y}, wherein x may be used to indicate the oxide being oxygen deficient compared to its full (or terminal) oxide and the value of x may be varied from the oxygen to metal atomic ratio in the stoichiometry of its full oxide, such as x≤2.0 for HfOₓ (where HfO₂ being the full oxide), and y≤2.5 for TaO_{y} (where Ta₂O₅ being the full oxide).

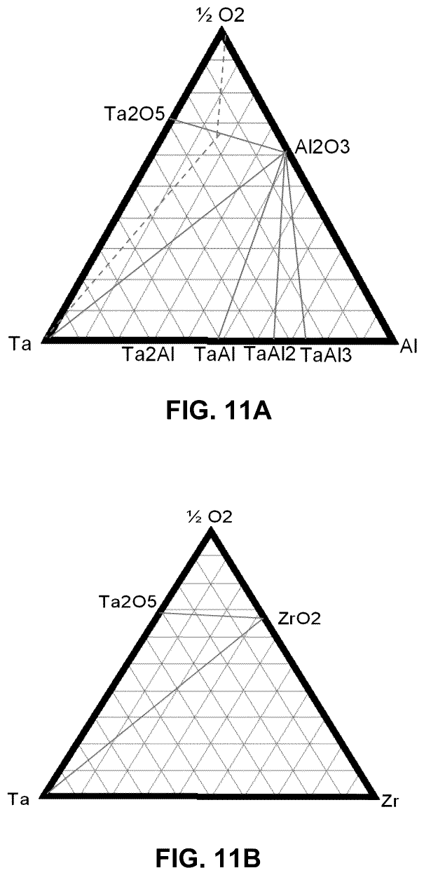

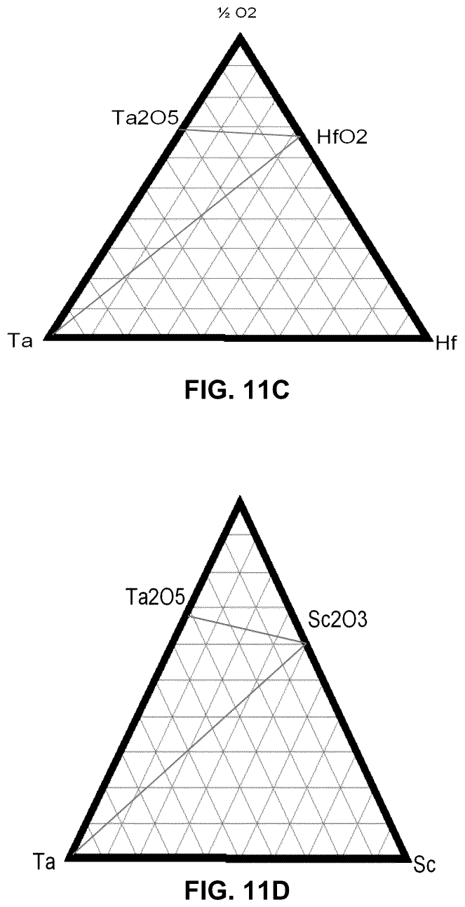

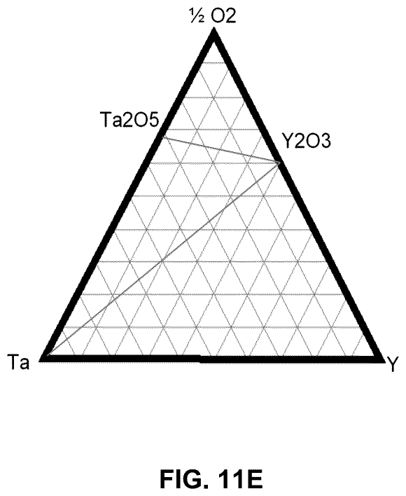

The switching oxide layer 330 may include one or more base oxides doped with one or more dopant oxides that are chemically more stable than the base oxide. In particular, the dopant oxides may have much more negative free energy of formation (or release more energy when oxygen forms an ionic bond with dopant metal than with base metal, or oxygen is preferred to form dopant oxide). For example, the base oxides may be Ta₂O₅. The dopant oxides may include, for example, Al₂O₃, ZrO₂, HfO₂, Sc₂O₃, Y₂O₃, etc. As a more particular example, the switching oxide layer 330 includes a layer of Ta₂O₅ doped with Al₂O₃. As shown in FIG. 11A, a Ta—Al—O ternary phase diagram shows that Al₂O₃ is the most stable phase, in equilibrium with Ta₂O₅, all phases in Ta—Al binaries, and the possible ternary compound TaAlO₄ (½ Ta₂O₅·Al₂O₃). When the switching oxide is Ta₂O₅ doped with Al₂O₃, Al₂O₃ may be in equilibrium with Ta₂O₅, the metastable suboxide TaO_{y}, and the Ta phase, with TaO_{y} and Ta being the metal-rich filamentary phase during switching. Al₂O₃ will always remain in a full oxidation state which can reduce the switching oxide current by reducing leakage current and thereby increasing the switching oxide resistance.

As another more particular example, the switching oxide layer 330 may include a layer of Ta₂O₅ doped with ZrO₂. As shown in FIG. 11B, a Ta—Zr—O ternary phase diagram shows that ZrO₂ is the most stable phase, in equilibrium with Ta₂O₅, the Ta phase, and the Zr phase. In the Ta—Zr binary, there are no intermetallic compounds. The Ta phase and the Zr phase are immiscible. When the switching oxide is Ta₂O₅ doped with ZrO₂, ZrO₂ will be in equilibrium with Ta₂O₅, the metastable suboxide TaO_{y}, and the Ta phase, with TaO_{y} and Ta serving as the metal-rich filamentary phase during switching operations. ZrO₂ may remain in a full oxidation state which may reduce the switching oxide current by reducing leakage current and increasing the switching oxide resistance.

As a further example, the switching oxide layer 330 may include a layer of Ta₂O₅ doped with HfO₂. As shown in FIG. 11C, a Ta—Hf—O ternary phase diagram indicates that HfO₂ is the most stable phase, in equilibrium with Ta₂O₅, the Ta phase, and the Hf phase. The Ta—Hf—O ternary is similar to the Ta—Zr—O ternary since Hf and Zr are both Group IVB elements in the periodic table. In the Ta—Zr binary, there are no intermetallic compounds, and the Ta phase and the Zr phase are immiscible. When the switching oxide is Ta₂O₅ doped with HfO₂, HfO₂ may be in equilibrium with Ta₂O₅, the metastable suboxide TaO_{y}, and the Ta phase, with TaO_{y} and Ta may be the metal-rich filamentary phase during switching. HfO₂ may remain in a full oxidation state which can reduce the switching oxide current by reducing leakage current and thereby increasing the switching oxide resistance.

As another more particular example, the switching oxide layer 330 includes a layer of Ta₂O₅ doped with Sc₂O₃. As shown in FIG. 11D, a Ta—Sc—O ternary phase diagram shows that Sc₂O₃ is the most stable phase, in equilibrium with Ta₂O₅, the Ta phase, and the Sc phase. Ta and Sc are immiscible, as no stable compounds were reported in the Ta—Sc binary. When the switching oxide is Ta₂O₅ doped with Sc₂O₃, Sc₂O₃ remains in the full oxidation state, which may reduce the switching oxide current by reducing leakage current and thereby increasing the switching oxide resistance.

As another more particular example, the switching oxide layer 330 includes a layer of Ta₂O₅ doped with Y₂O₃. As shown in FIG. 11E, a Ta—Y—O ternary phase diagram shows that Y₂O₃ is in the most stable phase, in equilibrium with the Ta₂O₅, the Ta phase, and the Y phase. Ta and Y are presumed to be immiscible, as no stable compounds were reported in the Ta—Y binary. The Ta—Y—O phase diagram is similar to the Ta—Sc—O phase diagram, as Sc and Y are group IIIB elements in the periodic table. When the switching oxide is Ta₂O₅ doped with Y₂O₃, Y₂O₃ remains in a full oxidation state, which may reduce the switching oxide current by reducing leakage current and thereby increasing the switching oxide resistance.

Referring to FIG. 3C, a second electrode 340 may be fabricated on the switching oxide layer 330 to fabricate an RRAM device 300c. The second electrode 340 may also be referred to as the “reactive electrode.” Second electrode 340 may include any suitable metallic material that is electronically conductive and reactive to the switching oxide. For example, the metallic material in second electrode 340 may include Ta, Hf, Ti, TiN, TaN, etc. Second electrode 340 may be reactive to the switching oxide and may have suitable oxygen solubility to adsorb some oxygen from the switching oxide layer 330 and create oxygen vacancies in the switching oxide layer 330. In other words, the reactive metallic material(s) in second electrode 340 may have suitable oxygen solubility and/or oxygen mobility. In some embodiments, second electrode 340 not only may be able to create oxygen vacancies in switching oxide layer 330 (e.g., by scavenging oxygen), but also may function as oxygen reservoir or source to the switching oxide layer 330 during cell programming.

In one implementation, second electrode 340 may include one or more alloys. Each of the alloys may contain two or more metallic elements. Each of the alloys may include a binary alloy (e.g., an alloy containing two metallic elements), a ternary alloy (e.g., an alloy containing three metallic elements), a quaternary alloy (e.g., an alloy containing four metallic elements), a quinary alloy (e.g., an alloy containing five metallic elements), a senary alloy (e.g., an alloy containing six metallic elements), and/or a high order alloy (e.g., an alloy containing more than six metallic elements). In some embodiments, the second electrode 340 may include one or more alloys containing a first metallic element and one or more second metallic elements. Each of the second metallic elements may be less or more reactive to the transition metal oxide in the switching oxide layer than the first metallic element. In some embodiments, the first metallic element may be Ta. The second metallic elements may include one or more of tungsten (W), hafnium (Hf), molybdenum (Mo), niobium (Nb), zirconium (Zr), etc. In some embodiments, the ratio of the first metallic element to the second metallic element(s) in an alloy in the second electrode 340 may be about 50 atomic percent. In some embodiments, the suitable ratio of the first metallic element to the second metallic element in the alloy may be optimized from the entire composition range. During a forming process, the second metallic element(s) may create fewer oxygen vacancies in the switching oxide layer than the first metallic element. As such, the lateral size of the filament formed in an RRAM device comprising a second electrode containing the alloy may be smaller than that of the filament formed in an RRAM device comprising a second electrode made of only the first metal.

In some implementations, second electrode 340 may include multiple layers of different metallic materials. For example, as shown in FIG. 3D, second electrode 340 may include a layer of titanium (Ti) 341 and a layer of tantalum (Ta) 343. The layer of Ti may be much thinner than the layer of Ta. For example, a thickness of the layer of Ti may be between about 0.2 nm and 5 nm. A thickness of the layer of Ta may be about 50 nm. In some embodiments, the thickness of the layer of Ti 341 may be between 0.3 nm and 2 nm. In some embodiments, the thickness of the layer of Ti 341 may be between 0.5 nm and 5 nm. In some embodiments, the thickness of the layer of Ti 341 may be between 0.5 nm and 2 nm. Both Ti and Ta may trap and release oxygen during device operations. The incorporation of the thin Ti layer into the RRAM device may change the virgin resistance of the RRAM device, result in a less abrupt forming process, reduce the forming voltage, reduce the reset current, and reduce voltage and/or current requirements in subsequent operation processes.

RRAM device 300c-d may have an initial resistance (also referred to herein as the “virgin resistance”) after it is fabricated. The initial resistance of RRAM device 300c-d may be changed and RRAM device 300c-d may be switched to a state of a lower resistance via a forming process. For example, a suitable voltage or current may be applied to RRAM device 300c-d. The application of the voltage to RRAM device 300c-d may induce the metallic material(s) in the second electrode to absorb oxygen from the switching oxide layer 330 and create oxygen vacancies in the switching oxide layer 330. As a result, a conductive channel (e.g., a filament) that is oxygen vacancy-rich may form in the switching oxide layer 330. For example, as illustrated in FIG. 3E, a conductive channel 335a may be formed in the switching oxide layer 330. As shown, conductive channel 335a may be formed from the second electrode 340 to the first electrode 320 across the switching oxide layer 330. RRAM device 300b may be reset to a high-resistance state. For example, a reset signal (e.g., a voltage signal or a current signal) may be applied to RRAM device 300b during a reset process. In some embodiments, the set signal and the reset signal may have opposite polarity, i.e., a positive signal and a negative signal, respectively. The application of the reset signal may cause oxygen to drift back to the switching oxide layer 330 and recombine with one or more of the oxygen vacancies. For example, an interrupted conductive channel 335b as shown in FIG. 3F may be formed in the switching oxide layer 330 during the reset process. As shown, the conductive channel may be interrupted with an oxide gap between the interrupted conductive channel 335b and the first electrode 320. The lateral dimension of the interrupted conductive channel 335b may be smaller than that of the conductive channel 335a. In some embodiments, the interrupted conductive channel 335b does not continuously connect the first electrode 320 and the second electrode 340. RRAM device 300c-d may be electrically switched between the high-resistance state and the low-resistance state by applying suitable programming signals (e.g., voltage signals, current signals, etc.) to the RRAM device.

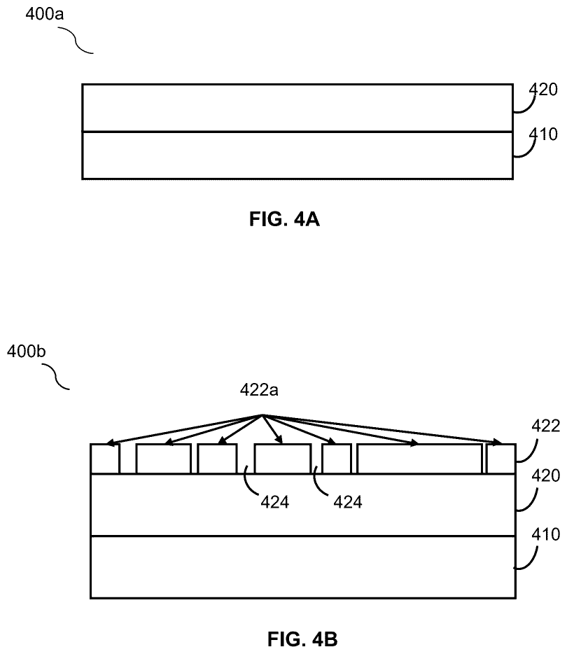

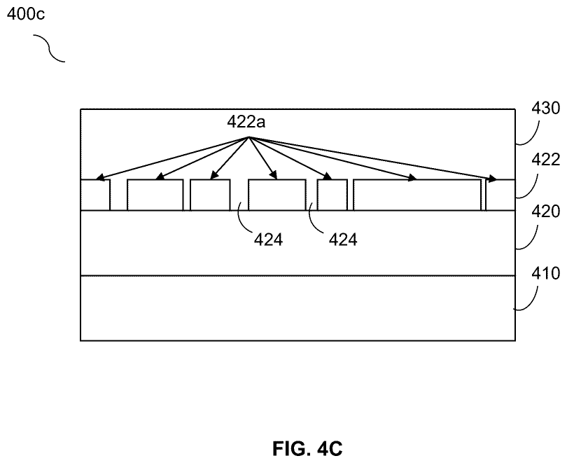

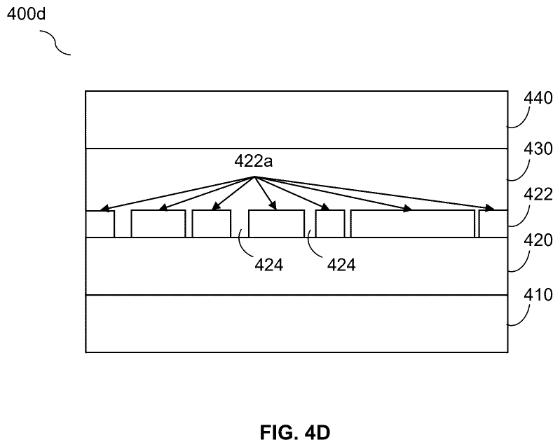

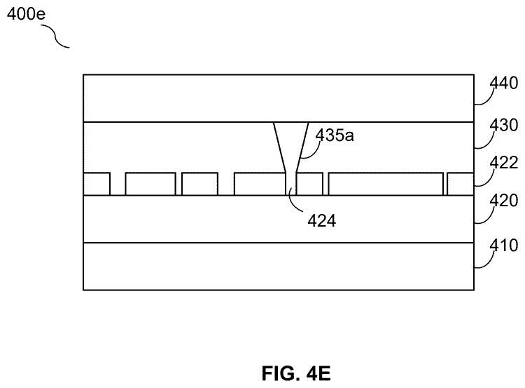

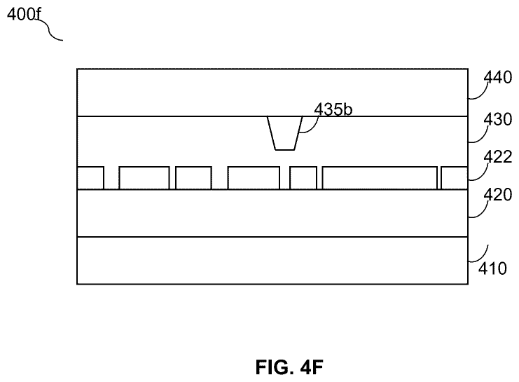

FIGS. 4A-4F are schematic diagrams illustrating cross-sectional views of example structures 400a, 400b, 400c, 400d, 400e, and 400f of RRAM devices in accordance with some embodiments of the present disclosure.

As illustrated FIG. 4A, a first electrode 420 may be fabricated on a substrate 410. The first electrode 420 and the substrate 410 may correspond to the first electrode 320 and the substrate 310 as described in conjunction with FIG. 3A, respectively.

As illustrated FIG. 4B, an interface layer 422 (also referred to as the “first interface layer”) may be fabricated on the first electrode 420. The interface layer 422 may be and/or include a discontinuous film 422a of a first dielectric material that is more chemically stable than the transition metal oxide(s) in the switching oxide layer to be fabricated on the interface layer 422. As a result, the dielectric material may not react with the transition metal oxide(s) in the switching oxide layer. In some embodiments, the first dielectric material may include a chemical element with a single valence state. As an example, the switching oxide layer may include a base oxide of HfOₓ and/or TaO_{y}, wherein x≤2.0, and wherein y≤2.5, and one or more dopant oxides (e.g., Al₂O₃, SiO₂, ZrO₂, Sc₂O₃, or Y₂O₃). The dielectric material may include one or more of Al₂O₃, SiO₂, Si₃N₄, MgO, Y₂O₃, Gb₂O₃, Sm₂O₃, CeO₂, Er₂O₃, La₂O₃, etc. The dielectric material does not react with the base oxide or the dopant oxide during setting processes and resetting processes.

As shown, the discontinuous film 422a may include pores and/or pin-holes 424 that are randomly dispersed in the interface layer 422. While a certain number of pores are illustrated in FIG. 4B, this is merely illustrative. The discontinuous film 422a may include any suitable number of pores and/or pin-holes. In some embodiments, a thickness of the interface layer 422 and/or the discontinuous film 422a may be between about 0.2 nm and about 0.5 nm. In some embodiments, the discontinuous film 422a may be an Al₂O₃ film having a thickness equal to or less than 0.5 nm. In some embodiments, the discontinuous film 422a may be and/or include an Al₂O₃ film having a thickness of less than 1 nm.

As illustrated in FIG. 4C, a switching oxide layer 430 may be fabricated on the interface layer 422. The switching oxide layer 430 may include one or more base oxides doped with one or more dopant oxides that are chemically more stable than the base oxide. In particular, the dopant oxides may have much more negative free energy of formation (or release more energy when oxygen forms an ionic bond with dopant metal than with base metal, or oxygen is preferred to form dopant oxide). For example, the base oxides may be Ta₂O₅. The dopant oxides may include, for example, Al₂O₃, ZrO₂, HfO₂, Sc₂O₃, Y₂O₃, etc.

In some embodiments, during the fabrication of the switching oxide layer 430, one or more portions of the transition metal oxides may be disposed on the first electrode 420 through one or more pores/pin-holes 424. As such, the switching oxide layer 430 may directly contact one or more portions of the first electrode 420. That is, one or more portions of the base oxide doped with the dopant oxide(s) may be deposited directly on the first electrode 420 through pores/pin-holes 424.

As shown in FIG. 4D, a second electrode 440 may be fabricated on the switching oxide layer 430. In some embodiments, the second electrode 440 may include the second electrode 340 described in connection with FIGS. 3C-3D.

FIGS. 4E and 4F illustrate RRAM devices 400e and 400f corresponding to a low-resistance state and a high-resistance state of RRAM device 400d, respectively. The incorporation of the interface layer 422 may reduce the contact area between the switching oxide layer 430 and the first electrode 420. As illustrated in FIG. 4E, a conductive channel 435a may be formed from the second electrode 440 to the first electrode 420 through the switching oxide layer 430 and the interface layer 422. As illustrated in FIG. 4F, an interrupted conductive channel 435b may be formed in the switching oxide layer 430 during the reset process. The incorporation of the interface layer 422 into the RRAM device may result in a less abrupt forming process, reduce the forming voltage, reduce the reset current, and reduce voltage and/or current requirements in subsequent operation processes.

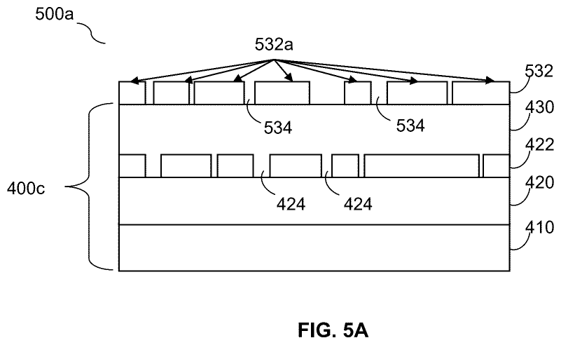

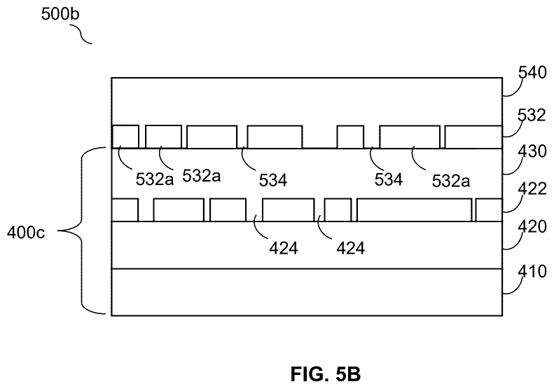

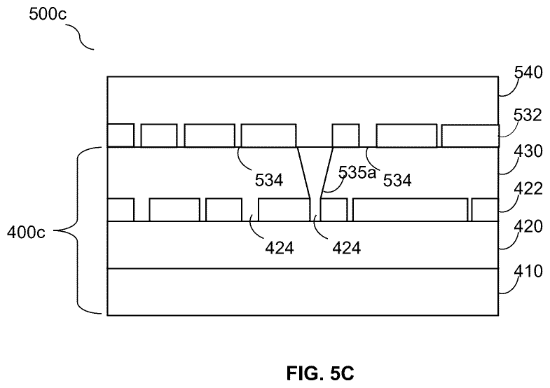

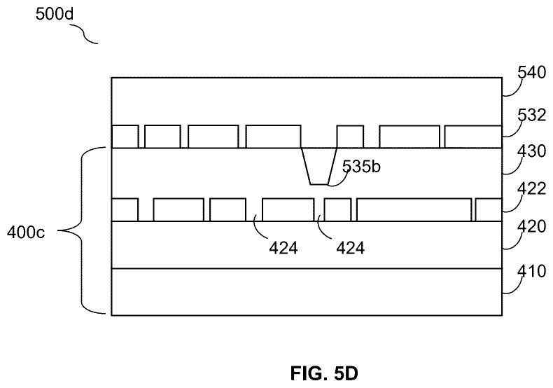

In some embodiments, an RRAM device may include multiple interface layers fabricated between the first electrode and the second electrode. Each of the interface layers may include a discontinuous film as described in connection with FIG. 4B. For example, as illustrated in FIG. 5A, a semiconductor device 500a may be fabricated by fabricating an interface layer 532 (also referred to as the “second interface layer”) on the structure 400c as described in connection with FIG. 4C. In some embodiments, the second interface layer 532 may include a discontinuous film 532a of a second dielectric material. The second dielectric material may be more chemically stable than the base oxide and the dopant oxide(s) in the switching oxide layer 430. As an example, the second dielectric material may include Al₂O₃, SiO₂, Si₃N₄, MgO, Y₂O₃, Gb₂O₃, Sm₂O₃, CeO₂, Er₂O₃, La₂O₃, etc. The second dielectric material may or may not be the same as the first dielectric material.

The discontinuous film 532a may include one or more pores and/or pin-holes 534 (also referred to as the “one or more second pores and/or pin-holes”). The pore(s) 534 may have any suitable size and/or dimension. Multiple pores 534 may or may not have the same size and/or dimension. In some embodiments, the second interface layer 532 and/or the second discontinuous film 532a may include multiple pores 534 dispersed randomly on the second interface layer 532. The discontinuous film 532a may include any suitable number of pores and/or pin-holes.

In some embodiments, a thickness of the second interface layer 532 and/or the second discontinuous film (also referred to as the “second thickness”) may be between about 0.2 nm and about 0.5 nm. As another example, the second interface layer 532 may include a discontinuous Al₂O₃ film having a thickness equal to or less than 0.5 nm. In some embodiments, the second interface layer 532 may include a discontinuous Al₂O₃ film having a thickness less than 1 nm. The second thickness of the second interface layer 532 may or may not be the same as the first thickness of the first interface layer 422.

As illustrated in FIG. 5B, a second electrode 540 may be fabricated on the second interface layer 532 to fabricate an RRAM device 500b. The second interface layer 532 is positioned between the switching oxide layer 430 and the second electrode 540. The second electrode 540 may be and/or include the second electrode 340 as described in conjunction with FIGS. 3C-3D. In some embodiments, during the fabrication of the second electrode 540, one or more portions of the second electrode 540 may be disposed on the switching oxide layer 430 through one or more pores and/or pin-holes 534. As such, the second electrode 540 may directly contact one or more portions of the switching oxide layer 430 through one or more pores/pin-holes 534.

FIGS. 5C and 5D illustrate semiconductor devices 500c and 500d that may correspond to a low-resistance state and a high-resistance state of the RRAM device 500b, respectively. The incorporation of both the first interface layer 422 and the second interface layer 532 may further reduce the contact area between the switching oxide layer 430 and the first electrode 420 and the contact area between the switching oxide layer 430 and the second electrode 540. As illustrated in FIG. 5C, a conductive channel 535a may be formed from the second electrode 540 to the first electrode 420 through the second interface layer 532, the switching oxide layer 430, and the first interface layer 420. As illustrated in FIG. 5D, an interrupted conductive channel 535b may be formed in the switching oxide layer 430 during the reset process.

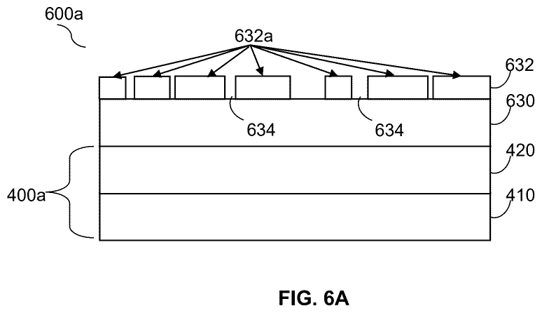

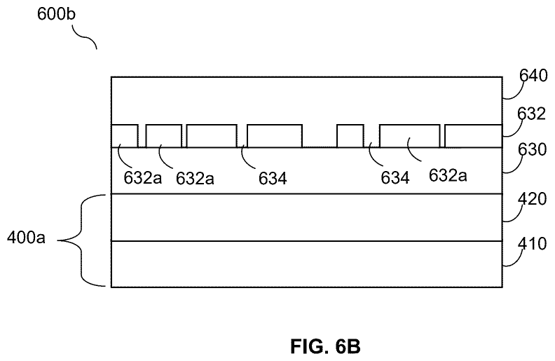

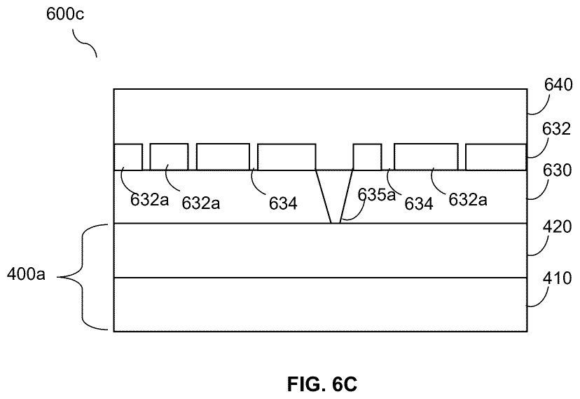

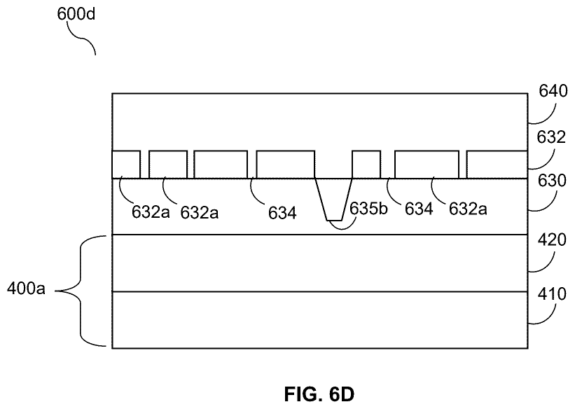

In some embodiments, an interface layer may be fabricated on a switching oxide layer of an RRAM device in accordance with some embodiments of the present disclosure. For example, as illustrated in FIG. 6A, a switching oxide layer 630 may be fabricated on the structure 400a as described in FIG. 4A. An interface layer 632 may be fabricated on the switching oxide layer 630 to fabricate an RRAM device 600a. The switching oxide layer 630 may be and/or include the switching oxide layer 430 as described in conjunction with FIGS. 4C-4D. In some embodiments, the interface layer 632 may include a discontinuous film of a dielectric material. The dielectric material may be more chemically stable than the base oxide and the dopant oxide in the switching oxide layer 630. As an example, the dielectric material may include Al₂O₃, MgO, Y₂O₃, La₂O₃, etc.

The discontinuous film 632a may include one or more pores and/or pin-holes 634. The pores/pin-holes 634 may have any suitable size and/or dimension and may be dispersed randomly on the interface layer 632. In some embodiments, a thickness of the interface layer 632 may be between about 0.2 nm and about 0.5 nm. As another example, the interface layer 632 may have a thickness equal to or less than 0.5 nm thickness. As a further example, the interface layer 632 may have a thickness of less than 1 nm.

As illustrated in FIG. 6B, a second electrode 640 may be fabricated on the interface layer 632 to fabricate an RRAM device 600b. The interface layer 632 may thus be positioned between the switching oxide layer 630 and the second electrode 640. The second electrode 640 may be and/or include the second electrode 440 described in conjunction with FIGS. 4D-4F. In some embodiments, during the fabrication of the second electrode 640, one or more portions of the second electrode 640 may be disposed on the switching oxide layer 630 through pores and/or pin-holes 634 and directly contact the switching oxide layer 630.

FIGS. 6C and 6D illustrate RRAM devices 600c and 600d corresponding to a low-resistance state and a high-resistance state of the RRAM device 600b, respectively. The incorporation of the interface layer 632 may reduce the contact area between the switching oxide layer 630 of the base oxide doped with dopant oxides and the second electrode 640. As illustrated in FIG. 6C, a conductive channel 635a may be formed from the second electrode 640 to the first electrode 420 through the interface layer 632 and the switching oxide layer 630. As illustrated in FIG. 6D, an interrupted conductive channel 635b may be formed in the switching oxide layer 630 during the reset process. The incorporation of the interface layer 632 into the RRAM device may result in a less abrupt forming process, reduce the forming voltage, reduce the reset current, and reduce voltage and/or current requirements in subsequent operation processes.

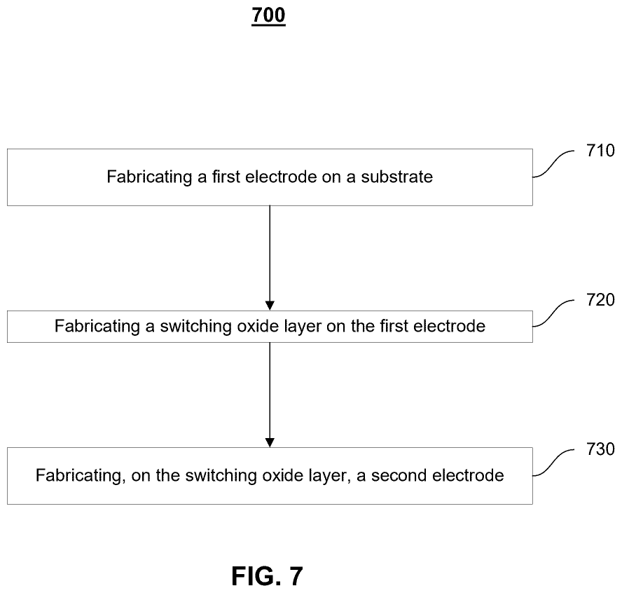

FIG. 7 is a flow diagram illustrating an example 700 of a method for fabricating an RRAM device according to some embodiments of the disclosure, including RRAM device 300c-300e in FIGS. 3C-3E.

At block 710, a first electrode may be fabricated on a substrate. In some embodiments, fabricating the first electrode may involve depositing one or more layers of a metal nitride, such as TiN, TaN, etc. For example, fabricating the first electrode may involve depositing one or more layers of TiN, utilizing an atomic layer deposition (ALD) technique, a physical vapor deposition (PVD) technique, a reactive sputtering of Ti technique, and/or any other suitable deposition technique. In some embodiments, fabricating the first electrode may involve depositing one or more layers of a non-reactive metal (e.g., Pt, Pd, Ir, Ru, etc.) using PVD, chemical vapor deposition (CVD), ALD, and/or other suitable deposition techniques. The first electrode may be and/or include the first electrode 320 as described in connection with FIG. 3A above. In some embodiments, a thin layer of an adhesion material, such as Ti, Ta, etc., may be fabricated between the substrate and the first electrode.

At block 720, a switching oxide layer may be fabricated on the first electrode. The switching oxide layer may include one or more layers of a base oxide doped with one or more dopant oxides. For example, the switching oxide layer may be and/or include switching oxide layer 330 as described in connection with FIG. 3B above. The dopant oxide is chemically more stable than the base oxide and may remain fully oxidized (e.g., in a full oxide state) to increase the resistivity of the switching oxide layer.

In some embodiments, the switching oxide layer may be fabricated utilizing an atomic layer deposition (ALD) process. The ALD process may involve depositing layers of the base oxide and one or more dopant oxides alternatively. For example, a deposition cycle of the ALD process may involve sequentially introducing a base oxide precursor and a dopant oxide precursor into an ALD chamber in which the first electrode is placed to deposit a layer of the base oxide and a layer of the dopant oxide. A suitable number of deposition cycles may be carried out to fabricate a switching oxide layer with a desired film thickness and/or dopant concentration. The number of base oxide deposition cycles and dopant oxide deposition cycles within each cycle can be adjusted to control the composition of the switching oxide film. For instance, a cycle comprising two to five base oxide deposition cycles and one to two dopant oxide deposition cycles will yield a switching oxide film with a controlled dopant oxide concentration.

In some embodiments, the switching oxide layer may be fabricated using a PVD (Physical Vapor Deposition) process. For example, a co-sputtering process may be utilized. In the co-sputtering process, two or more separate targets may be used to sputter materials simultaneously onto the first electrode. Specifically, a base oxide and one or more dopant oxides may be co-sputtered onto the first electrode. By adjusting the power supplied to each target, the composition ratio of the base oxide to the dopant oxide in the deposited film (i.e., the switching oxide layer) can be controlled. This results in a switching oxide layer comprising the base oxide doped with the dopant oxide on the first electrode. In some embodiments, in the reactive co-sputtering process, both base metal and dopant metal utilize a combined sputter gas of argon and oxygen (Ar and O₂). By adjusting the flow ratio of Ar to O₂, modulating the power applied to the base metal target and the dopant metal target, and controlling the opening and closing of the target shutters, precise control over the composition of the switching oxide is achieved. The dopant oxide has a predilection for oxidation. Hence, through reactive co-sputtering, full oxidation of the dopant oxide may be realized, enabling the control over the concentration of oxygen vacancies present in the base oxide.

In some embodiments, the switching oxide layer may be fabricated utilizing a single target in a PVD process. For example, the PVD process may involve fabricating a single target by combining powders of the base oxide and dopant oxide in desired proportions. The base oxide and dopant oxide ratio may determine the doping concentration in the final switching oxide layer. A sintering process may be performed after achieving a homogeneous mixture of the base oxide and dopant oxide powders. The sintering process may involve pressing and heating the powders until they bond together, without reaching their melting point, resulting in a single integrated target of the base oxide and the dopant oxide(s). The top surface of the first electrode may be cleaned and/or prepared for deposition of the switching oxide layer. The single target may be introduced into a PVD chamber. The target may be bombarded with ions (e.g., from an inert gas such as Argon) using a single power source. This ion bombardment may cause atoms or clusters from the target comprising both the base oxide and dopant oxide to be ejected from the target surface. The sputtered atoms or clusters from the target then travel through the vacuum and deposit on the substrate, forming a thin film of the base oxide doped with the dopant oxide.

Using a single target may further streamline the PVD process by eliminating the need to switch between targets or adjust multiple power sources. This integration not only saves time but also increases throughput. Moreover, two different oxides can be combined in the same target, allowing for improved process control in deposition. The PVD process may further improve the throughput by eliminating the temperature requirements of certain ALD processes. Additionally, electrodes can be deposited using PVD, allowing the first electrode, the switching oxide layer, and the second electrode of the RRAM device to be fabricated in the same PVD chamber.

At block 730, a second electrode may be fabricated on the switching oxide layer. Fabricating the second electrode may involve fabricating one or more layers of one or more metallic materials that are electronically conductive and reactive to the switching oxide. For example, fabricating the second electrode may involve depositing one or more layers of Ta, utilizing CVD, ALD, PVD, and/or any other suitable deposition technique. In some embodiments, fabricating the second electrode may further involve fabricating a layer of a CMOS-compatible metal and/or a CMOS-compatible nitride. The second electrode may be and/or include second electrode 340 as described in connection with FIGS. 3C-3D above. In some embodiments, fabricating the second electrode may involve fabricating a first layer of a first metallic material and a second layer of a second metallic material (e.g., layers 341 and 343 of FIG. 3F). The first layer of the first metallic material may be fabricated by depositing a first metal (e.g., Ti metal) utilizing PVD, CVD, sputtering, ALD, and/or any other suitable deposition technique. Fabricating the first layer of the first metal may involve depositing a layer of the first metal with a suitable thickness, such as a thickness between about 0.2 nm and about 5 nm, a thickness between about 0.3 nm and about 2 nm, etc. Fabricating the second layer of the second metallic material may involve depositing a second metal (e.g., Ta metal) utilizing PVD, CVD, sputtering, ALD, and/or any other suitable deposition technique. Fabricating the second layer of the second metal may involve depositing a layer of the second metal with a suitable thickness, such as a layer of the second metal that is thicker than that of the first layer of the first metal. In some embodiments, a layer of the second metal having a thickness between 10 nm and 100 nm may be deposited. In some embodiments, the second layer of the second metal may be deposited directly on the first layer of the first metal. In such embodiments, a surface of the first layer of the first metal may directly contact a surface of the second layer of the second metal.

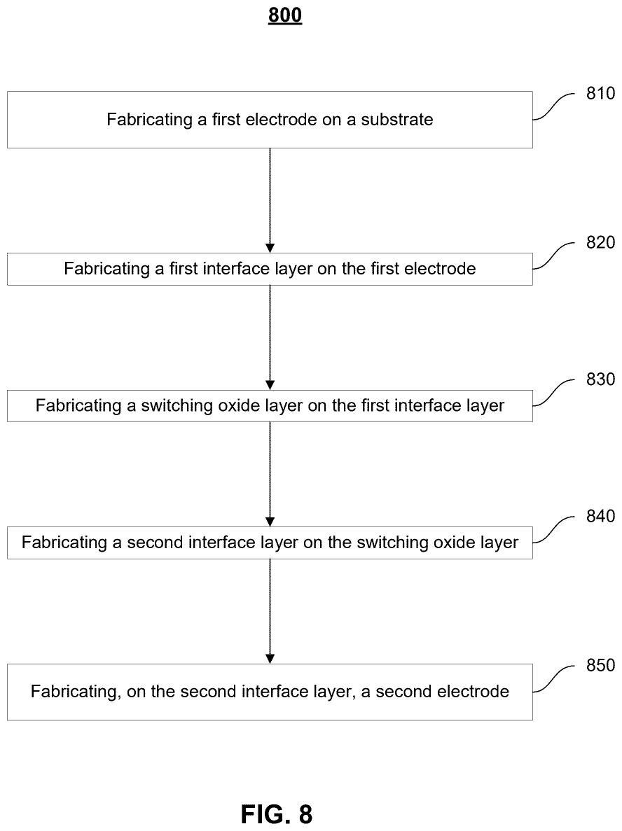

FIG. 8 is a flow diagram illustrating an example 800 of a process for fabricating an RRAM device according to some embodiments of the disclosure, including RRAM device 500b in FIG. 5B.

At block 810, a first electrode may be fabricated on a substrate. Blocks 810 and 710 may be executed in substantially the same manner. The first electrode may be and/or include first electrode 420 as described in connection with FIG. 5B above.

At block 820, a first interface layer may be fabricated on the first electrode. The first interface layer may include a material that is more chemically stable than the transition metal oxide(s) of the switching oxide layer (such as AlOₓ, like Al₂O₃) described subsequently. For example, fabricating the first interface layer may involve depositing AlOₓ, utilizing an atomic layer deposition (ALD) technique, a physical vapor deposition (PVD) technique, a reactive sputtering of Al technique, and/or any other suitable deposition technique. The first interface layer may be and/or include the interface layer 422 as described in connection with FIG. 5B above.

At block 830, a switching oxide layer comprising one or more base oxides doped with one or more dopant oxides may be fabricated on the first interface layer. The switching oxide layer may be and/or include switching oxide layer 430 described in connection with FIG. 5B above. Block 830 may be performed in substantially the same manner as block 720. In some embodiments in which the first interface layer is a discontinuous layer of a dielectric layer, one or more portions of the base oxides doped with the dopant oxides may be directly deposited on the first electrode through the pin-holes and/or pores in the first interface layer.

At block 840, a second interface layer may be fabricated on the switching oxide layer. The second interface layer may include a material that is more chemically stable than the transition metal oxide(s) of the switching oxide layer, such as AlOₓ, like Al₂O₃. For example, fabricating the second interface layer may involve depositing AlOₓ, utilizing an ALD technique, a physical vapor deposition (PVD) technique, a reactive sputtering of Al technique, and/or any other suitable deposition technique. The second interface layer may be and/or include the interface layer 532 as described in connection with FIG. 5B above.

At block 850, a second electrode may be fabricated on the second interface layer. The second electrode may be and/or include the second electrode 540 as described in connection with FIG. 5B above. Blocks 850 and 730 may be performed in substantially the same manner.

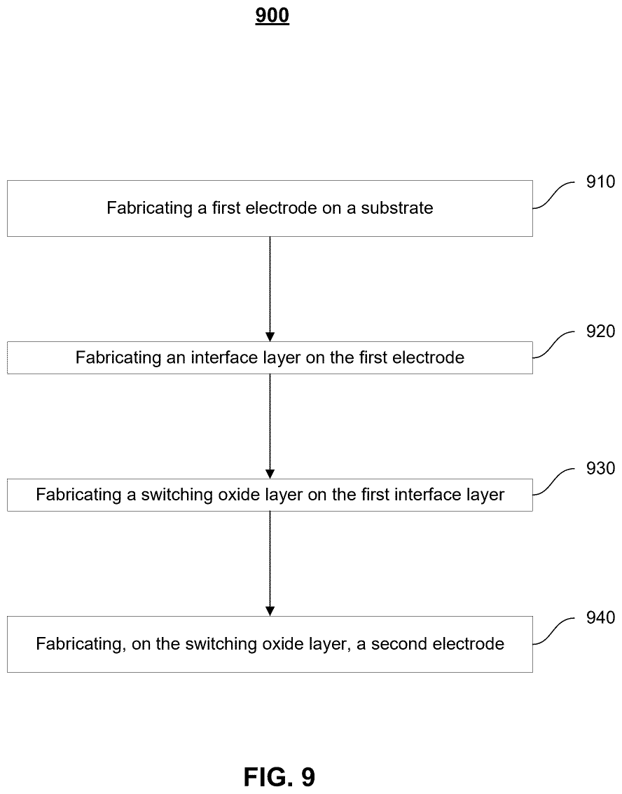

FIG. 9 is a flow diagram illustrating an example 900 of a process for fabricating an RRAM device according to some embodiments of the disclosure, including RRAM device 400d in FIG. 4D.

At block 910, a first electrode may be fabricated on a substrate. Blocks 910 and 710 may be executed in substantially the same manner. The first electrode may be and/or include first electrode 420 as described in connection with FIG. 4D above.

At block 920, an interface layer may be fabricated on the first electrode. The first interface layer may include a material that is more chemically stable than the transition metal oxide(s) of the switching oxide layer (such as AlOₓ, like Al₂O₃) described subsequently. For example, fabricating the first interface layer may involve depositing AlOₓ, utilizing an atomic layer deposition (ALD) technique, a physical vapor deposition (PVD) technique, a reactive sputtering of Al technique, and/or any other suitable deposition technique. The first interface layer may be and/or include the interface layer 422 as described in connection with FIG. 4D above.

At block 930, a switching oxide layer comprising one or more base oxides and one or more dopant oxides may be fabricated on the first interface layer. The switching oxide layer may be and/or include switching oxide layer 430 as described in connection with FIG. 4D above. Block 930 may be performed in substantially the same manner as block 720.

At block 940, a second electrode may be fabricated on the switching oxide layer. Blocks 940 and 730 may be executed in substantially the same manner. The second electrode may be and/or include second electrode 440 as described in connection with FIG. 4D above.

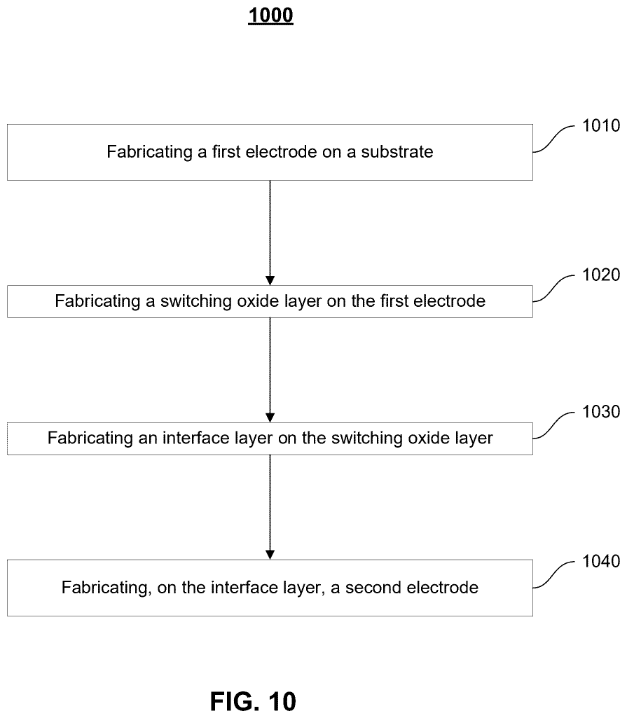

FIG. 10 is a flow diagram illustrating an example 1000 of a process for fabricating an RRAM device according to some embodiments of the disclosure, including RRAM device 600b in FIG. 6B.

At block 1010, a first electrode may be fabricated on a substrate. Blocks 1010 and 710 may be executed in substantially the same manner. The first electrode may be and/or include first electrode 420 as described in connection with FIG. 6B above.

At block 1020, a switching oxide layer comprising one or more based oxides and one or more dopant oxides may be fabricated on the first interface layer. The transition metal oxides may include, e.g., HfOₓ. For example, fabricating the switching oxide layer may involve depositing HfOₓ, utilizing an ALD technique, a PVD technique, a reactive sputtering of Hf technique, and/or any other suitable deposition technique. The switching oxide layer may be and/or include switching oxide layer 630 described in connection with FIG. 6B above. Block 1020 may be performed in substantially the same manner as block 720.

At block 1030, an interface layer may be fabricated on the switching oxide layer. The second interface layer may include a material that is more chemically stable than the transition metal oxide(s) of the switching oxide layer, such as AlOₓ, like Al₂O₃. For example, fabricating the second interface layer may involve depositing AlOₓ, utilizing an ALD technique, a physical vapor deposition (PVD) technique, a reactive sputtering of Al technique, and/or any other suitable deposition technique. The second interface layer may be and/or include the interface layer 632 as described in connection with FIG. 6B above.

At block 1040, a second electrode may be fabricated on the second interface layer. Blocks 1040 and 850 may be executed in substantially the same manner. The second electrode may be and/or include the second electrode 640 as described in connection with FIG. 6B above.

FIG. 11A is an example Ta—Al—O ternary phase diagram. As illustrated, Al₂O₃ is the most stable phase, coexisting in equilibrium with Ta₂O₅, all phases in Ta—Al binaries, as well as the possible ternary compound TaAlO₄ (½ Ta₂O₅·Al₂O₃).

FIG. 11B is an example Ta—Zr—O ternary phase diagram. As illustrated, Zr₂O₂ is the most stable phase, coexisting in equilibrium with Ta₂O₅, Ta phase, and Zr phase. Within the Ta—Zr binary, no intermetallic compounds are present, and the Ta phase and the Zr phase are immiscible.

FIG. 11C is an example Ta—Hf—O ternary phase diagram. As illustrated, HfO₂ is the most stable phase, coexisting in equilibrium with Ta₂O₅, the Ta phase, and the Hf phase. The Ta—Hf—O ternary is similar to the Ta—Zr—O ternary, as both Hf and Zr are Group IVB elements in the periodic table. With the Ta—Zr binary, there are no intermetallic compounds, and the Ta phase and the Zr phase are immiscible.

FIG. 11D is an example Ta—Sc—O ternary phase diagram. As shown, Sc₂O₃ is the most stable phase, coexisting in equilibrium with Ta₂O₅, the Ta phase, and the Sc phase. Ta and Sc are presumed to be immiscible, as no stable compounds have been reported in the Ta—Sc binary. A ternary phase TaScO₄ (½ Ta₂O₅·Sc₂O₃) on the tie-line Ta₂O₅—Sc₂O₃ does not affect the stability of Sc₂O₃ phase.

FIG. 11E is an example Ta—Y—O ternary phase diagram. As shown, Y₂O₃ is the most stable phase, coexisting in equilibrium with Ta₂O₅, the Ta phase, and the Y phase. Ta and Y are presumed to be immiscible, as no stable compounds have been identified in the Ta—Y binary. The Ta—Y—O phase diagram is similar to the Ta—Sc—O phase diagram, as both Sc and Y are Group IIIB elements in the periodic table.

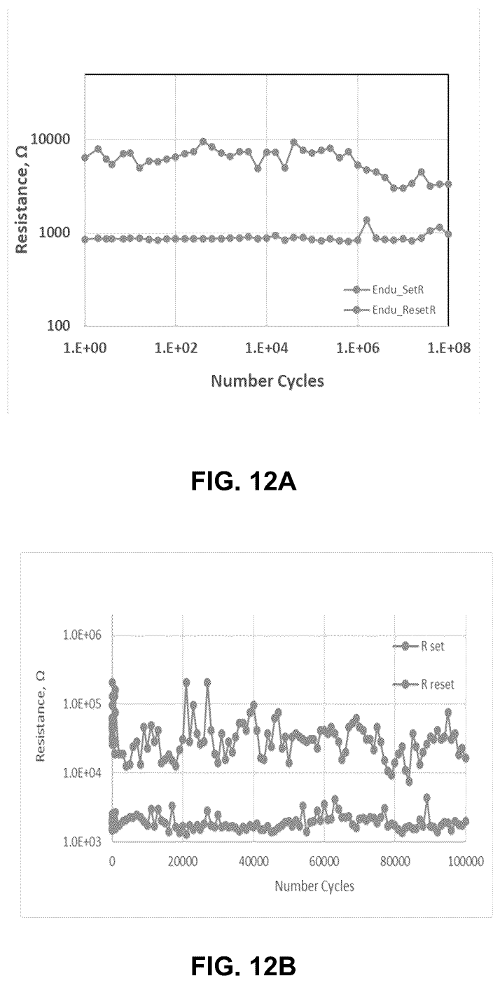

FIGS. 12A and 12B are diagrams plotting the resistance of example RRAM devices according to the present disclosure over a number of operation cycles. FIG. 12A shows an example RRAM device with 100 million endurance cycles at room temperature. The RRAM device includes a switching oxide layer of TaO_{y} doped with Al₂O₃. FIG. 12B shows an example RRAM device with 1 million endurance cycles at 125° C. The RRAM device includes a switching oxide layer of TaO_{y} doped with Al₂O₃. As shown, the RRAM devices present desirable operational stability and endurance during both set and reset operations.

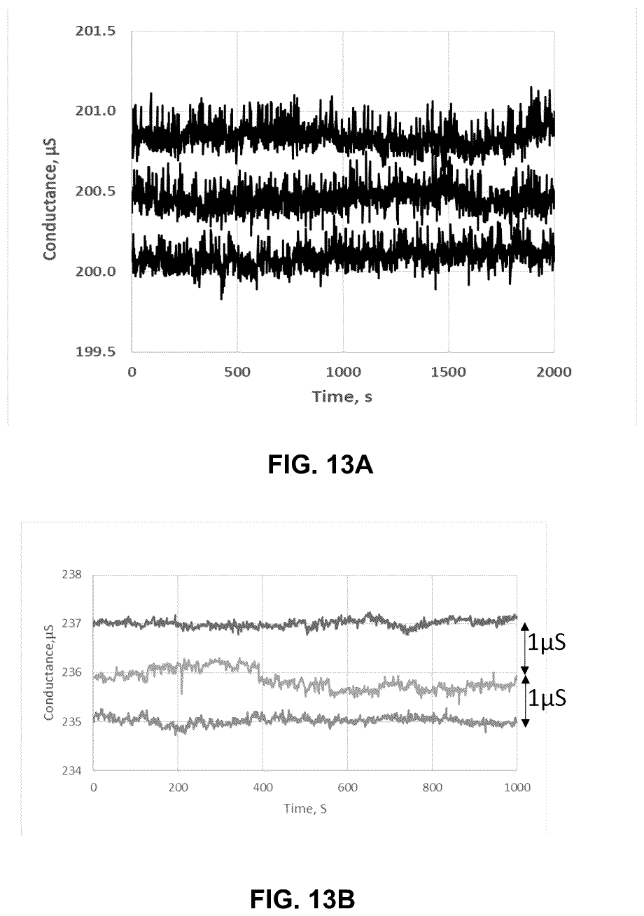

FIGS. 13A and 13B are diagrams plotting the conductance of an example RRAM device according to the present disclosure over time at room temperature and 125° C., respectively. FIG. 13A shows an example RRAM device with multi-level read stability at room temperature. The example RRAM device includes a switching oxide layer of TaO_{y} doped with Al₂O₃. FIG. 13B shows an example RRAM device with multi-level read stability at 125° C. The example RRAM device includes a switching oxide layer of TaO_{y} doped with Al₂O₃. As shown, the example RRAM device presents good read stability (e.g., 0.5 μS/level at room temperature, 1 μS/level at 125° C.). This stability represents crucial multi-level analog behavior for in-memory computing.

For simplicity of explanation, the methods of this disclosure are depicted and described as a series of acts. However, acts in accordance with this disclosure can occur in various orders and/or concurrently, and with other acts not presented and described herein. Furthermore, not all illustrated acts may be required to implement the methods in accordance with the disclosed subject matter. In addition, those skilled in the art will understand and appreciate that the methods could alternatively be represented as a series of interrelated states via a state diagram or events.

The terms “approximately,” “about,” and “substantially” as used herein may mean within a range of normal tolerance in the art, such as within 2 standard deviations of the mean, within +20% of a target dimension in some embodiments, within +10% of a target dimension in some embodiments, within +5% of a target dimension in some embodiments, within +2% of a target dimension in some embodiments, within +1% of a target dimension in some embodiments, and yet within +0.1% of a target dimension in some embodiments. The terms “approximately” and “about” may include the target dimension. Unless specifically stated or obvious from context, all numerical values described herein are modified by the term “about.”

As used herein, a range includes all the values within the range. For example, a range of 1 to 10 may include any number, combination of numbers, sub-range from the numbers of 1, 2, 3, 4, 5, 6, 7, 8, 9, and 10 and fractions thereof.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. A resistive random-access memory (RRAM) device, comprising:
a first electrode;
a second electrode comprising a conductive material; and
a switching oxide layer fabricated between the first electrode and the second electrode, wherein the switching oxide layer comprises a base oxide and a dopant oxide that is more chemically stable than the base oxide, wherein the first electrode comprises a non-reactive material that is not reactive to the base oxide or the dopant oxide.

2. The RRAM device of claim 1, wherein the base oxide comprises at least one of HfOₓ or TaO_{y}, wherein x≤2.0, and wherein y≤2.5.

3. The RRAM device of claim 1, wherein the base oxide comprises Ta₂O₅, wherein the dopant oxide comprises at least one of Al₂O₃, SiO₂, ZrO₂, Sc₂O₃, or Y₂O₃.

4. The RRAM device of claim 3, wherein the non-reactive material in the first electrode comprises at least one of titanium nitride, tantalum nitride, platinum, palladium, iridium, or ruthenium.

5. The RRAM device of claim 4, wherein the second electrode further comprises a layer of titanium and a layer of tantalum.

6. The RRAM device of claim 1, further comprising an interface layer positioned between the switching oxide layer and the second electrode.

7. The RRAM device of claim 6, wherein the interface layer positioned between the switching oxide layer and the second electrode comprises a discontinuous film of a dielectric material, wherein at least a portion of the second electrode is deposited on the switching oxide layer.

8. The RRAM device of claim 1, further comprising a first interface layer positioned between the first electrode and the switching oxide layer.

9. The RRAM device of claim 8, further comprising a second interface layer positioned between the second electrode and the switching oxide layer.

10. A method for fabricating an RRAM device, comprising:
fabricating, on a first electrode, a switching oxide layer on the first electrode comprising a base oxide and a dopant oxide, wherein the dopant oxide is more chemically stable than the base oxide; and
fabricating a second electrode on the switching oxide layer.

11. The method of claim 10, wherein the base oxide comprises at least one of HfOₓ or TaO_{y}, wherein x≤2.0, and wherein y≤2.5.

12. The method of claim 10, wherein the base oxide comprises Ta₂O₅, wherein the dopant oxide comprises at least one of Al₂O₃, SiO₂, ZrO₂, Sc₂O₃, or Y₂O₃.

13. The method of claim 12, wherein fabricating the switching oxide layer comprises performing physical vapor deposition (PVD) using a single target comprising the base oxide and the dopant oxide and a single power source.

14. The method of claim 13, wherein the first electrode, the switching oxide layer, and the second electrode are fabricated in the same physical vapor deposition (PVD) processing chamber.

15. The method of claim 12, wherein fabricating the switching oxide layer comprises performing a physical vapor deposition (PVD) co-sputtering process.

16. The method of claim 12, wherein fabricating the switching oxide layer comprises depositing the base oxide and the dopant oxide using an atomic layer deposition (ALD) process.

17. The method of claim 11, further comprising fabricating an interface layer on the switching oxide layer.

18. The method of claim 17, wherein the interface layer comprises a discontinuous film of a dielectric material, wherein at least a portion of the second electrode is deposited on the switching oxide layer comprising the base oxide and the dopant oxide.

19. The method of claim 18, wherein the dielectric material comprises at least one of Al₂O₃, SiO₂, ZrO₂, Sc₂O₃, or Y₂O₃.

20. The method of claim 11, further comprising:
fabricating a first interface layer comprising a first dielectric material on the first electrode, wherein the switching oxide layer is fabricated on the first interface layer; and
fabricating a second interface layer comprising a second dielectric material on the switching oxide layer, wherein the second electrode is fabricated on the second interface layer.
